(19) United States
(12) Patent Application Publication
(10) Pub. No.: US 2026/0008025 A1
(43) Pub. Date: Jan. 8, 2026

(54) High pressure microwave plasma reactors

(71) Applicant: MAAT Energy Company, Cambridge, MA (US)

(72) Inventors: Kim-Chinh Tran, Cambridge, MA (US); Leslie Bromberg, Sharon, MA (US); Jorj Ian Owen, Bowie, MD (US); Jonathan Whitlow, Melbourne Beach, FL (US)

(21) Appl. No.: 18/992,287

(22) PCT Filed: Jul. 10, 2023
(86) PCT No.: PCT/US2023/027258

§ 371 Date: Jan. 8, 2025

Related U.S. Application Data
(60) Provisional application No. 63/359,959, filed on Jul. 11, 2022.

(51) Int. Cl. B01J 19/12

(52) U.S. Cl. CPC B01J 19/126; B01J 2219/0875; B01J 2219/0896; B01J 2219/1227; B01J 2219/1239; B01J 2219/1269

(57) ABSTRACT

A variety of microwave-based plasma reactors are presented which are intended for operation at high pressures, from 0.1 to 10 bar, and a high flow rate. Further, reactors can operate without the presence of a dielectric material, which can degrade in time requiring replacement and causing downtime for the unit. Applications for these devices include heating, reforming, and pyrolyzing the reactants.

### CLAIM OF PRIORITY

This disclosure claims priority to U.S. Provisional Application No. 63/359,959, filed Jul. 11, 2022, the disclosure of which is incorporated by reference in its entirety.

### STATEMENT OF GOVERNMENT-SPONSORED RESEARCH

This invention was made with government support under grant numbers DE-SC0019791 and DE-SC0021783, awarded by the United States Department of Energy, Small Business Innovation Research. The government has certain rights in the invention.

### FIELD OF INVENTION

The present invention relates generally to microwave-based plasma devices intended to operate at a high pressure, 0.1 to 10 bar, and a high flow rate. Further, these systems can operate without the presence of a dielectric material, which can degrade in time requiring replacement and causing downtime for the unit.

### BACKGROUND OF THE INVENTION

Microwave-based plasma reactor systems can be used to heat, reform, or pyrolyze reactants. In the case of reforming and pyrolysis reactants are converted into a molecularly different product. For industrial applications it is desirable to operate plasma reactor systems at high flow rate and high pressures as the equipment is smaller and energy intensive vacuum systems can be avoided. Containing the reactant and reliably delivering the microwaves to the reactants has been a challenge.

Others have disclosed plasma systems which can be operated at high pressure by using dielectric tubes to contain the flow of reactants, see for example US2022/0022293A1, US2010/0322827A1, and US2012/0034137A1. Similarly, reactors with dielectric windows directly on the microwave-based plasma reactor have been disclosed, see US9, 293, 302B2. The presence dielectric tubes, windows, or in other forms can present challenges for long-term operation of microwave-based plasma systems. The different coefficients of thermal expansion for the dielectric material and the metallic reactor can make sealing the reactants in the reactor a challenge. While O-rings of Teflon, rubber, or other materials can be used to help seal, such materials come with their own temperature limitations, that are generally well below the melting point of the metallic reactor.

Two-phase flows, where both solids and gases are present in the plasma, can be used in reforming and pyrolysis applications, see for example US10, 434, 490B2 and US11, 583, 814. The presence of a dielectric in a two-phase flow is especially challenging for plasma reactor that have dielectric materials, as the solid materials can deposit on the dielectric surface. Often the solids absorb microwaves and will locally heat, damaging the dielectric material.

By avoiding the use of dielectric material in the microwave-based plasma reactor maintenance and down time can be greatly reduced. Further the costs associated with the use of consumable materials such as dielectric tubes and windows can be voided.

### SUMMARY OF THE INVENTION

Here we disclose various microwave-based plasma reactors that operate at high pressure and do not contain dielectric materials in the plasma reactor. The operating pressure of the plasma reactor is preferably between 0.1 and 10 bar. More preferably the operating pressure is between 0.95 and 5 bar.

Microwaves generally refer to electromagnetic radiation having a frequency between 300 MHz and 300 GHz. In our experience a single reactor cannot be effective across the whole microwave spectrum, and reactors must be designed to a specific frequency radiation. As such, when describing the reactors, the dimensions of the microwave reactors are given in terms of the wavelength (in free-space) being used. In this way the reactor designs could be applied across the whole microwave spectrum, as the dimensions will scale with the wavelength, rather than limited to commonly used portions of the spectrum such as the ultra-high frequency band (300-3000 MHZ) and the S-band (2-4 GHZ).

It is worth noting that microwave radiation generators such as magnetrons and solid-state generators produce a spectrum of microwave radiation, there is a dominant peak in the wavelength spectrum, the plasma reactors are designed toward utilizing this dominant peak. Throughout this specification the dominant peak in wavelength will simply be referred to as the wavelength of the microwave radiation.

### BRIEF DESCRIPTION OF THE DRAWINGS

To better illustrate the invention and to aid in a more thorough description which provides other advantages and objectives of the invention the following drawings are referenced. It is noted that these embodiments are specific examples of the invention and not to be understood as limiting cases for the scope of this invention.

References to directions such as bottom/top, upward/downward refer to the figures used for illustration rather than orientation of the device during use. Further, the drawings are intended to emphasize relations between the various elements, as such the elements are not to scale. The drawings are as follows:

FIG. 1: First cross-sectional view of the atmospheric microwave plasma reactor according to the first embodiment.

FIG. 2: Second cross-sectional view of the atmospheric microwave plasma reactor according to the first embodiment, second embodiment, third embodiment, sixth embodiment, and seventh embodiment.

FIG. 3: Cross-sectional view of the atmospheric microwave plasma reactor according to the second embodiment.

FIG. 4: Cross-sectional view of the atmospheric microwave plasma reactor according to the third embodiment.

FIG. 5: First cross-sectional view of the atmospheric microwave plasma reactor according to the fourth embodiment.

FIG. 6: Second cross-sectional view of the atmospheric microwave plasma reactor according to the fourth embodiment.

FIG. 7: First cross-sectional view of the atmospheric microwave plasma reactor according to the fifth embodiment.

FIG. 8: Second cross-sectional view of the atmospheric microwave plasma reactor according to the fifth embodiment.

FIG. 9: Cross-sectional view of the atmospheric microwave plasma reactor according to the sixth embodiment.

FIG. 10: Projection of the tapered microwave inlet of the atmospheric microwave plasma reactor according to the sixth embodiment.

FIG. 11: Cross-sectional view of the atmospheric microwave plasma reactor according to the seventh embodiment.

### DETAILED DESCRIPTION OF THE INVENTION

For simplicity elements in the first embodiment are given numbers in the one hundreds, elements in the second embodiment are given numbers in the two hundreds, and so forth. Many of the embodiments contain elements that are equivalent, in such cases the final two digits of the element number will match. For example, the top flange 105 is equivalent to the top flange 205. In this way the differences between the various embodiments can be focused on, rather than redescribing elements that are essentially the same.

### Embodiment 1

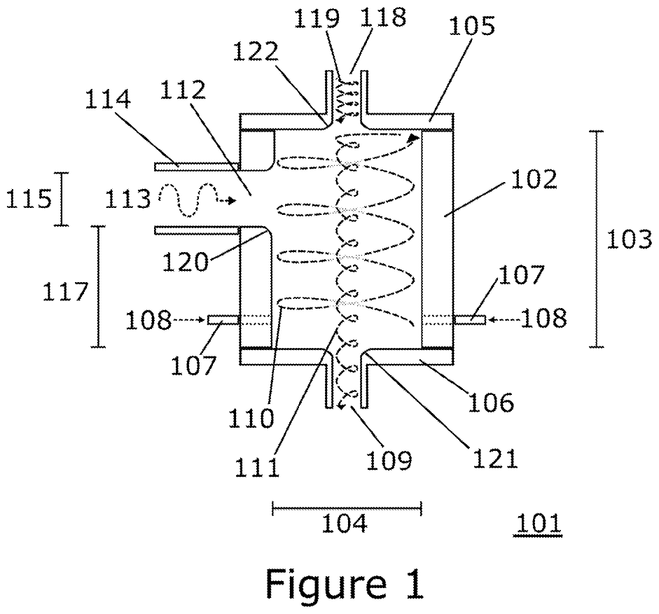

FIG. 1 gives a first cross-sectional diagram through the axial center of an atmospheric microwave plasma reactor according to the first embodiment 101. The plasma reactor according to the first embodiment comprises a reactor body 102 which has a cylindrical inner surface having a height 103 and a diameter 104. The plasma reactor according to the first embodiment also comprises a top flange 105 and a bottom flange 106 which are airtight and in electrical contact with the reactor body 102. At least one swirl reactant inlet 107 for the injection of a first portion of reactants 108 penetrates the reactor body 102. To introduce swirl the swirl reactant inlet 107 has tangential component to the angle of entry into the reactor body 102. The dotted line in FIG. 1 for the portion of the swirl reactant inlet 107 through the reactor body 102 indicates that the cross-sectional diagram through the axial center would not show the path for the whole inlet. The bottom flange 106 includes an outlet 109. The flow rate of the first portion of reactants 108 and inner diameter of the swirl reactant inlet(s) 107, are chosen such that the first portion of reactants flow in an upward helical flow 110 along the inner surface of the reactor body 102 towards the top flange 105. Near the top flange 105 the flow continues in the same rotational direction (clockwise or counterclockwise) but moves towards the center of the reactor body 102 and increases angular velocity to conserve angular momentum, this downward helical flow 111 flows through the center of the reactor body 102 towards the bottom flange 106, exiting through the outlet 109.

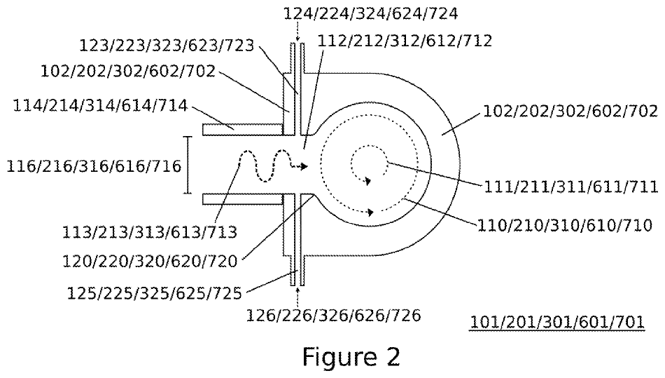

The plasma reactor according to the first embodiment also comprises a microwave inlet 112 through which microwave radiation 113 enters the reactor body 102. The microwave radiation 113 is guided to the reactor body 102 via a waveguide 114. The microwave radiation 113 is preferably in transverse electric one zero (TE10) mode, where the electric field is perpendicular to the direction of propagation, and the waveguide 114 has a E-plane dimension 115 that is less than the H-plane dimension 116 (see FIG. 2). The bottom edge of the microwave inlet 112 and the bottom of the reactor body 102 are separated by a distance 117.

A top reactant inlet 118 may be included in the top flange 105. A second portion of reactants 119 may be injected through the top reactant inlet 118. The second portion of reactants 119 may be injected with a downward helical flow 111 having the same spin direction as the first portion of reactants 108 (as shown if FIG. 1), alternatively the second portion of reactants 119 may be injected purely axially or counter to the first portion of reactants 108.

A waveguide rounded edge 120 is preferably included where the microwave inlet 112 penetrates the reactor body 102. An outlet rounded edge 121 is preferably included where the outlet 109 penetrates the bottom flange 106. A top inlet rounded edge 122 is preferably included where the top reactant inlet 118 penetrates the top flange 105.

FIG. 2 gives a second cross-sectional diagram through the center of the microwave inlet 112 perpendicular to the axial center of the atmospheric microwave plasma reactor according to the first embodiment 101. While the upward helical flow 110 and downward helical flow 111 are depicted as counterclockwise they could alternatively be made clockwise by adjusting the angle of the tangential component of the swirl reactant inlet 107. A congruent flow sweeper gas inlet 123 penetrates the reactor body 102 allowing a third portion of reactants 124 to flow into the microwave inlet 112 in the same general direction as the upward helical flow 110 and the downward helical flow 111. A counter flow sweeper gas inlet 125 penetrates the reactor body 102 allowing a fourth portion of reactants 126 to flow into the microwave inlet 112 opposite the general direction of the upward helical flow 110 and the downward helical flow 111. The congruent flow sweeper gas inlet 123 and counter flow sweeper gas inlet 125 and the respective third portion of reactants 124 and fourth portion of reactants 126 can be used to reduce the portion of the upward helical flow 110 that enters the microwave inlet 112. This is particularly important when solids are processed or formed in the plasma reactor. Additionally, these flows can be pulsed to push solid deposits out of the microwave inlet 112.

For the microwave radiation 113 to form a plasma within the reactor body 102 of the plasma reactor according to the first embodiment 101 the dimensions of the cylindrical inner surface height 103, the cylindrical inner surface diameter 104, and the distance 117 between the bottom of the microwave inlet and the bottom of the reactor body 102 are dependent on the wavelength of the microwave radiation 113. For a given microwave radiation 113 having a (dominant) free-space wavelength of A, the cylindrical inner surface height 103 (L1) is preferably 0.6λ≤L1≤1.6λ, more preferably 0.8λ≤L1≤1.2λ. The cylindrical inner surface diameter 104 (d1) is preferably 0.5λ≤d1≤1.3λ, more preferably 0.6λ≤d1≤0.9λ. The distance 117 between the bottom of the microwave inlet and the bottom of the reactor body 102 (L2) is preferably 0.5Δ≤L2≤0.75λ, more preferably 0.55λ≤L2≤0.65λ.

The selection of the size of the microwave inlet 112 is also very important to the operation of the plasma reactor according to the first embodiment 101. If the E-plane dimension 115 is too small the electric field in the microwave inlet may be large enough to cause plasma formation within the microwave inlet 112; the plasma may progress into the waveguide 114 and even damage the microwave source further upstream. If the H-plane dimension 116 is too small the bulk or all the microwave radiation 113 may be reflected and no plasma is formed within the reactor body 102. On the other hand, the larger the E-plane dimension 115 and H-plane dimension 116 are the more the fluid dynamics of the upward helical flow 110 and downward helical flow 111 may be disturbed, which may prevent the stable formation of a plasma within the reactor body 102. For unloaded waveguides (i.e., without a dielectric), the E-plane dimension 115 (E1) is preferably 0.15λ≤E1≤0.45λ, more preferably 0.3λ≤E1≤0.4λ. The H-plane dimension 116 (H1) is preferably 0.5λ≤H1≤0.9λ, more preferably 0.6λ≤H1≤0.8λ.

Rounding sharp edges in the reactor helps prevent the formation regions with an undesirably high electric field. Such regions can cause plasma discharges to the inner walls of the plasma reactor. Including the waveguide rounded edge 120, outlet rounded edge 121, and top inlet rounded edge 122 (when a top reactant inlet is included) will improve performance and extend the life of the plasma reactor. The waveguide rounded edge 120, outlet rounded edge 121, and top inlet rounded edge 122 preferably have a radius of curvature (r1) where 0.02λ≤r1≤0.2λ, more preferably 0.03λ≤r1≤0.1λ.

While FIG. 1 depicts two swirl reactant inlets 107 a single or more than two swirl reactant inlets 107 could also be used. Further, although FIG. 1 depicts the swirl reactant inlets 107 penetrating the reactor body 102 with a tangential component to the angle, additional or alternatively the swirl reactant inlets 107 could be part of the bottom flange 106 as long as there is a tangential component to the angle to drive the upward helical flow 110.

To form a stable plasma within the plasma reactor according to the first embodiment 101 the flow rates of the first portion of reactants 108 (r1), second portion of reactants 119 (r2), third portion of reactants 124 (r3), and fourth portion of reactants 126 (r4) must be controlled. If too low the flow of reactants will not maintain the desired upward helical flow 110 and downward helical flow 111, but rather a laminar flow from the various inlets to the outlet 109. On the other hand, if the flows of reactants are too high turbulence may cause the plasma formed to become unstable. Preferably the volume of the sum of reactants flowing (R=r1+r2+r3+r4) into the plasma reactor according to the first embodiment 101 is related to the volume of the reactor body 102 V=πL1(d1/2)\hat{ }2 through the residence time tau (volume of the reactor divided by the volume throughput of the reactants): the residence time should be 0.2<tau<1.5 seconds, or preferably 0.5<tau<1 seconds. To maintain the desired fluid dynamics the majority of the reactants flowing through the reactor are injected as the first portion of reactants 108, preferably 0.75≤r1/R≤1, more preferably 0.8≤r1/R≤1. The combined surface area of the single or multiple swirl reactant inlet(s) 107 will determine the velocity the first portion of reactants 108. If the velocity is too low a laminar flow to the outlet 109 may form rather than the desired upward helical flow 110 and downward helical flow 111. On the other hand, if the velocity is too high the flow may be choked by sonic conditions and the turbulent flows may make the plasma unstable. To maintain the desired fluid dynamics the velocity (v) of the first portion of reactants 108 exiting the swirl reactant inlet 107 are preferably 0.2≤v/v_sound≤0.9, more preferably 0.5≤v/v_sound≤0.7, where v_sound is the sound speed in the reactants introduced through the inlet at the gas temperature at the inlet. The reactants may be preheated.

### Embodiment 2

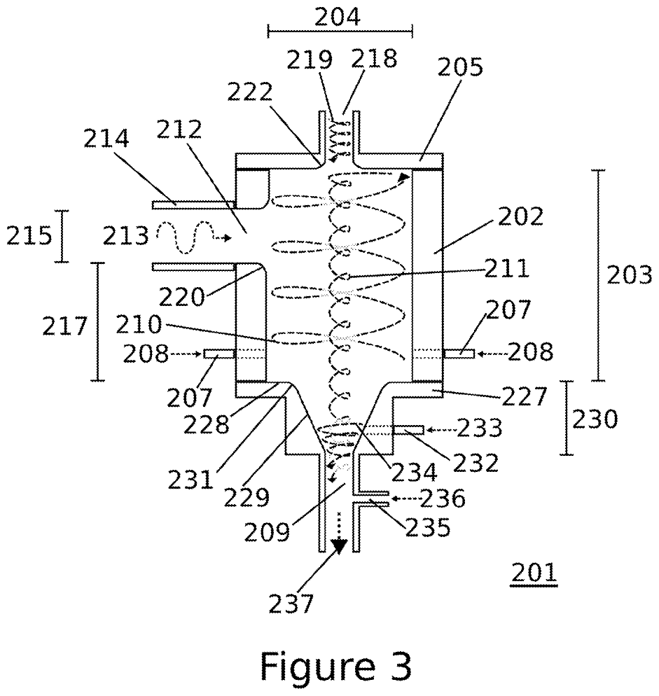

FIG. 3 gives a cross-sectional diagram through the axial center of an atmospheric microwave plasma reactor according to the second embodiment 201. Equivalent elements to previously described embodiments are not repeated, details can be found with the initial description above. Further a second cross-sectional diagram through the center of the microwave inlet is not provided as it is equivalent to that of the first embodiment, see FIG. 2.

In the second embodiment 201 the bottom flange 106 of the first embodiment 101, is replaced with a conical bottom flange 227 which is airtight and in electrical contact with the reactor body 202. The conical bottom flange 227 may have a ledge 228 which helps to drive the upward helical flow 210. The conical bottom flange 227 further has a conical inner surface 229 which tapers from the diameter of the ledge 228 to the diameter of the outlet 209, the taper occurring over a cone height 230. A conical flange rounded edge 231 is preferably included to avoid sharp features between the ledge 228 and the conical inner surface 229. Alternatively, the ledge 228 and the conical flange rounded edge 231 can be omitted, leaving a conical inner surface 229 having a diameter equal to the diameter of the cylindrical inner surface diameter 204.

The conical bottom flange 227 may include a conical flange inlet 232, for the injection of a fifth portion of reactants 233, which may produce a cone swirl flow 234 when the conical flange inlet 232 has tangential component to the angle of entry into the conical bottom flange 227. The dotted line in FIG. 3 for the portion of the conical flange inlet 232 through the conical bottom flange 227 indicates that the cross-sectional diagram through the axial center would not show the path for the whole inlet. Preferably the swirl direction of the downward helical flow 211 and the cone swirl flow 234 will be the same, as this will help maintain plasma stability.

As the downward helical flow 211 and the cone swirl flow 234 progress through the outlet 209 an exhaust inlet 235 may introduce a sixth portion of reactants 236. As shown in FIG. 3, the sixth portion of reactants 236 may be introduced axially, which may cause a turbulent mixing region as the flows come together, while downstream a laminar flow 237 will result. An exhaust inlet 235 may be applied, for example, when quenching or when rapid mixing is required.

For the microwave radiation 213 to form a plasma within the reactor body 202 of the plasma reactor according to the second embodiment 201 the dimensions of the cylindrical inner surface height 203, the cylindrical inner surface diameter 204, the distance 217 between the bottom of the microwave inlet and the bottom of the reactor body, and the cone height 230 are dependent on the wavelength of the microwave radiation 113. For a given microwave radiation 213 having a (dominant) free-space wavelength of λ, the cylindrical inner surface height 203 (L1) is preferably 0.5λ≤L1≤0.9λ, more preferably 0.65λ≤L1≤0.8λ. The cylindrical inner surface diameter 204 (d1) is preferably 0.7λ≤d1≤1.1λ, more preferably 0.8λ≤d1≤1.1λ. The distance 217 between the bottom of the microwave inlet and the bottom of the reactor body (L2) is preferably 0.1λ≤L2≤0.3λ, more preferably 0.15λ≤L2≤0.25λ. The cone height 230 (L3) is preferably 0.15λ≤L3≤0.6λ, more preferably 0.4λ≤L3≤0.5λ. The preferred angle of the cone is 15 degrees to 50 degrees, more preferably between 20 degrees and 30 degrees.

The selection of the size of the microwave inlet 212 is also very important to the operation of the plasma reactor according to the second embodiment 201. For unloaded waveguides (i.e., without a dielectric), the E-plane dimension 215 (E1) is preferably 0.15λ≤E1≤0.45λ, more preferably 0.3λ≤E1≤0.4λ. The H-plane dimension 216 (H1) is preferably 0.5λ≤H1≤0.9λ, more preferably 0.6λ≤H1≤0.8λ.

Including the waveguide rounded edge 220, top inlet rounded edge 222 (when a top reactant inlet 218 is included), and conical flange rounded edge 231 will improve performance and extend the life of the plasma reactor. The waveguide rounded edge 220, top inlet rounded edge 222, and conical flange rounded edge 231 preferably have a radius of curvature (rc1) where 0.02λ≤rc1≤0.2λ, more preferably 0.03λ≤rc1≤0.1λ.

While FIG. 3 depicts two swirl reactant inlets 207, a single or more than two swirl reactant inlets 207 could also be used. Further, although FIG. 3 depicts the swirl reactant inlets 207 penetrating the reactor body 202 with a tangential component to the angle, additional or alternatively the swirl reactant inlets 207 could be part of the conical bottom flange 227 on the ledge 228 if there is a tangential component to the angle to drive the upward helical flow 210.

To form a stable plasma within the plasma reactor according to the second embodiment 201 the flow rates of the first portion of reactants 208 (r1), second portion of reactants 219 (r2), third portion of reactants 224 (r3) (through the congruent flow sweeper gas inlet 223), fourth portion of reactants 226 (r4) (through the counter flow sweeper gas inlet 225), and fifth portion of reactants 233 (r5) must be controlled. Preferably the volume of the sum of reactants flowing (R=r1+r2+r3+r4+r5) into the plasma reactor according to the second embodiment 201 is related to the volume of the reactor body 202 V=πL1 (d1/2)\hat{ }2 through the residence time tau (volume of the reactor divided by the volume throughput of the reactants): the residence time should be 0.2<tau<1.5 seconds, or preferably 0.5<tau<1 seconds. To maintain the desired fluid dynamics the majority of the reactants flowing through the reactor are injected as the first portion of reactants 208, preferably 0.75≤r1/R≤1, more preferably 0.8≤r1/R≤1. The combined surface area of the single or multiple swirl reactant inlet(s) 207 will determine the velocity the first portion of reactants 208. To maintain the desired fluid dynamics the velocity (v) of the first portion of reactants 208 exiting the swirl reactant inlet 207 are preferably 0.2≤v/v_sound≤0.9, more preferably 0.5≤v/v_sound≤0.7, where v_sound is the sound speed in the reactants introduced through the inlet at the gas temperature at the inlet. The reactants may be preheated.

### Embodiment 3

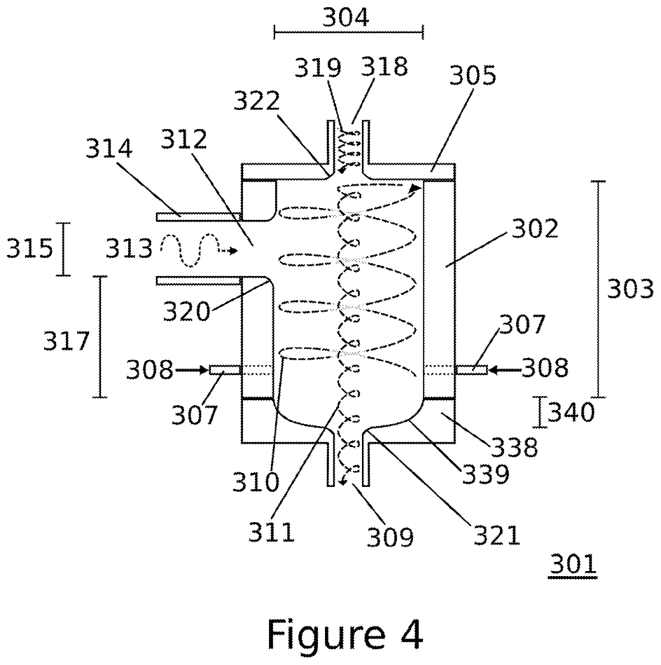

FIG. 4 gives a cross-sectional diagram through the axial center of an atmospheric microwave plasma reactor according to the third embodiment 301. Equivalent elements to previously described embodiments are not repeated, details can be found with the initial description above. Further a second cross-sectional diagram through the center of the microwave inlet is not provided as it is equivalent to that found in FIG. 2.

In the third embodiment 301 the bottom flange 106 of the first embodiment 101, is replaced with a bowl bottom flange 338 which is airtight and in electrical contact with the reactor body 302. The bowl bottom flange 338 has a bowl inner surface 339 which curves from the diameter of the cylindrical inner surface 304 to the diameter of the outlet 309, forming a smooth transition over a bowl height 340. Thus, there are no sharp transitions between the reactor body 302 and the bowl bottom flange 338, which may improve plasma stability.

Although not show, tangential or exhaust inlets could be included in the bowl bottom flange 338 as described in the second embodiment 201.

For the microwave radiation 313 to form a plasma within the reactor body 302 of the plasma reactor according to the third embodiment 301 the dimensions of the cylindrical inner surface height 303, the cylindrical inner surface diameter 304, the distance 317 between the bottom of the microwave inlet and the bottom of the reactor body, and the bowl height 340 are dependent on the wavelength of the microwave radiation 313. For a given microwave radiation 313 having a (dominant) free-space wavelength of λ, the cylindrical inner surface height 303 (L1) is preferably 0.5λ≤L1≤0.9λ, more preferably 0.65λ≤L1≤0.8λ. The cylindrical inner surface diameter 304 (d1) is preferably 0.7λ≤d1≤1.1λ, more preferably 0.8λ≤d1≤0.95λ. The distance 317 between the bottom of the microwave inlet and the bottom of the reactor body (L2) is preferably 0.1λ≤L2≤0.3λ, more preferably 0.15λ≤L2≤0.25λ. The radius of curvature of the bowl inner surface 339 (rc2) is preferably 1.5λ≤rc2≤3.5λ, more preferably 2.2λ≤rc2≤2.8λ.

The selection of the size of the microwave inlet 312 is also very important to the operation of the plasma reactor according to the third embodiment 301. For unloaded waveguides (i.e., without a dielectric), the E-plane dimension 315 (E1) is preferably 0.15λ≤E1≤0.45λ, more preferably 0.3λ≤E1≤0.4λ. The H-plane dimension 316 (H1) is preferably 0.5λ≤H1≤0.9λ, more preferably 0.6λ≤H1≤0.8λ.

Including the waveguide rounded edge 320, top inlet rounded edge 322 (when a top reactant inlet 318 is included), and outlet rounded edge 321 will improve performance and extend the life of the plasma reactor. The waveguide rounded edge 320, top inlet rounded edge 322, and outlet rounded edge 321 preferably have a radius of curvature (rc1) where 0.02λ≤rc1≤0.2λ, more preferably 0.03λ≤rc1≤0.1λ.

While FIG. 4 depicts two swirl reactant inlets 307, a single or more than two swirl reactant inlets 307 could also be used. Further, although FIG. 4 depicts the swirl reactant inlets 307 penetrating the reactor body 302 with a tangential component to the angle, additional or alternatively the swirl reactant inlets 307 could be part of the bowl bottom flange 338 if there is a tangential component to the angle to drive the upward helical flow 310 followed by the downward helical flow 311.

To form a stable plasma within the plasma reactor according to the third embodiment 301 the flow rates of the first portion of reactants 308 (r1), second portion of reactants 319 (r2), third portion of reactants 324 (r3) (through the congruent flow sweeper gas inlet 323), and fourth portion of reactants 326 (r4) (through the counter flow sweeper gas inlet 325) must be controlled. Preferably the volume of the sum of reactants flowing (R=r1+r2+r3+r4) into the plasma reactor according to the third embodiment 301 is related to the volume of the reactor body 302 V=πL1(d1/2)\hat{ }2 through the residence time tau (volume of the reactor divided by the volume throughput of the reactants): the residence time should be 0.2<tau<1.5 seconds, or preferably 0.5<tau<1 seconds. To maintain the desired fluid dynamics the majority of the reactants flowing through the reactor are injected as the first portion of reactants 308, preferably 0.75≤r1/R≤1, more preferably 0.8≤r1/R≤1. The combined surface area of the single or multiple swirl reactant inlet(s) 307 will determine the velocity the first portion of reactants 308. To maintain the desired fluid dynamics the velocity (v) of the first portion of reactants 308 exiting the swirl reactant inlet 307 are preferably 0.2≤ v/v_sound≤0.9, more preferably 0.5≤v/v_sound≤0.7, where v_sound is the sound speed in the reactants introduced through the inlet at the gas temperature at the inlet. The reactants may be preheated.

### Embodiment 4

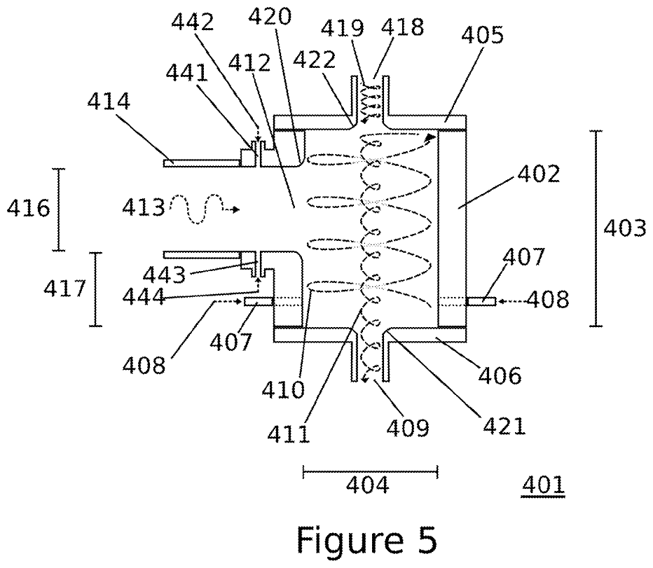

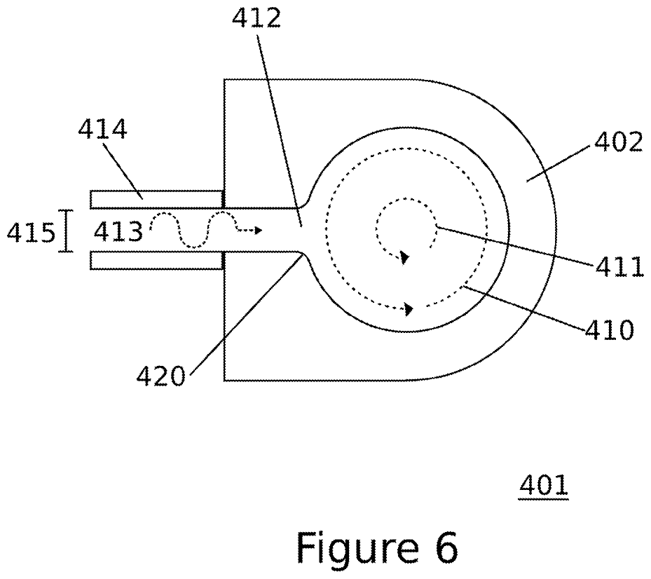

FIG. 5 gives a first cross-sectional diagram through the axial center of an atmospheric microwave plasma reactor according to the fourth embodiment 401. FIG. 6 gives a second cross-sectional diagram through the center of the microwave inlet 412 perpendicular to the axial center of the atmospheric microwave plasma reactor according to the fourth embodiment 401. Equivalent elements to previously described embodiments are not repeated, details can be found with the initial description above.

In the fourth embodiment 401 the microwave inlet 412 has been rotated by 90 degrees, as compared to the microwave inlet 112 of the first embodiment 101. In this case, the broader H-plane dimension 416 is oriented vertically along the axis through the axial center of the fourth embodiment 401 (see FIG. 5), while the narrower E-plane dimension 415 is perpendicular (see FIG. 6). Thus, in FIG. 5 the height of microwave inlet 412 is increased as compared to the microwave inlet 112 in FIG. 1. While in FIG. 6 the width of the microwave inlet 412 is decreased as compared to the microwave inlet 112 in FIG. 2. The waveguide 414 has also been rotated by 90 degrees to match the microwave inlet 412 dimensions. The microwave radiation 413 is preferably in transverse electric one zero (TE10) mode, where the electric field is perpendicular to the direction of propagation. The bottom edge of the microwave inlet 412 and the bottom of the reactor body 402 are separated by a distance 417. By rotating the microwave inlet 412 the upward helical flow 410 crosses the narrower E-plane dimension 415 with every rotation, this may help better maintain the desired fluid flow pattern through the plasma reactor, increasing plasma stability.

The fourth embodiment 401 may additionally include a waveguide top sweeper gas inlet 441 through which a seventh portion of reactants 442 can be injected, as well as a bottom sweeper gas inlet 443 through which an eighth portion of reactants 444 can be injected. The waveguide top sweeper gas inlet 441 and the bottom sweeper gas inlet 443 and the respective seventh portion of reactants 442 and eighth portion of reactants 444 can be used to reduce the portion of the upward helical flow 410 that enters the microwave inlet 412. This is particularly important when solids are processed or formed in the plasma reactor.

Additionally, these flows can be pulsed to push solid deposits out of the microwave inlet 412. While inlets similar to the congruent flow sweeper gas inlet 123 and counter flow sweeper gas inlet 125 of the first embodiment 101 could be included, with the 90 degree rotation of the microwave inlet 412 in the fourth embodiment 401 such inlets would penetrate the H-plane and may have high electric fields which could encourage plasma formation in the microwave inlet 412.

For the microwave radiation 413 to form a plasma within the reactor body 402 of the plasma reactor according to the fourth embodiment 401 the dimensions of the cylindrical inner surface height 403, the cylindrical inner surface diameter 404, and the distance 417 between the bottom of the microwave inlet and the bottom of the reactor body are dependent on the wavelength of the microwave radiation 413. For a given microwave radiation 413 having a (dominant) free-space wavelength of A, the cylindrical inner surface height 403 (L1) is preferably 0.6λ≤L1≤1.3λ, more preferably 0.8λ≤L1≤1.15λ. The cylindrical inner surface diameter 404 (d1) is preferably 0.45λ≤d1≤0.95λ, more preferably 0.6λ≤d1≤0.75λ. The distance 417 between the bottom of the microwave inlet and the bottom of the reactor body (L2) is preferably 0.1Δ≤L2≤0.3λ, more preferably 0.15λ≤L2≤0.25λ.

The selection of the size of the microwave inlet 412 is also very important to the operation of the plasma reactor according to the fourth embodiment 401. For unloaded waveguides (i.e., without a dielectric), the E-plane dimension 415 (E1) is preferably 0.15λ≤E1≤0.45λ, more preferably 0.3λ≤E1≤0.4λ. The H-plane dimension 416 (H1) is preferably 0.5λ≤H1≤0.9λ, more preferably 0.6λ≤H1≤0.8λ.

Including the waveguide rounded edge 420, outlet rounded edge 421, and top inlet rounded edge 422 (when a top reactant inlet 418 is included) will improve performance and extend the life of the plasma reactor. The waveguide rounded edge 420, outlet rounded edge 421, and top inlet rounded edge 422 preferably have a radius of curvature (rc1) where 0.02λ≤rc1≤0.2λ, more preferably 0.03λ≤rc1≤0.1λ.

While FIG. 5 depicts two swirl reactant inlets 407, a single or more than two swirl reactant inlets 407 could also be used. Further, although FIG. 5 depicts the swirl reactant inlets 407 penetrating the reactor body 402 with a tangential component to the angle, additional or alternatively the swirl reactant inlets 407 could be part of the bottom flange 406 if there is a tangential component to the angle to drive the upward helical flow 410 followed by the downward helical flow 411.

To form a stable plasma within the plasma reactor according to the fourth embodiment 401 the flow rates of the first portion of reactants 408 (r1), second portion of reactants 419 (r2), seventh portion of reactants 442 (r7), and eighth portion of reactants 444 (r8) must be controlled. Preferably the volume of the sum of reactants flowing (R=r1+r2+r7+r8) into the plasma reactor according to the fourth embodiment 401 is related to the volume of the reactor body 402 V=πL1(d1/2)\hat{ }2 through the residence time tau (volume of the reactor divided by the volume throughput of the reactants): the residence time should be 0.2<tau<1.5 seconds, or preferably 0.5<tau<1 seconds. To maintain the desired fluid dynamics the majority of the reactants flowing through the reactor are injected as the first portion of reactants 408, preferably 0.75≤r1/R≤1, more preferably 0.8≤r1/R≤1. The combined surface area of the single or multiple swirl reactant inlet(s) 407 will determine the velocity the first portion of reactants 408. To maintain the desired fluid dynamics the velocity (v) of the first portion of reactants 408 exiting the swirl reactant inlet 407 are preferably 0.2≤v/v_sound≤0.9, more preferably 0.5≤v/v_sound≤0.7, where v_sound is the sound speed in the reactants introduced through the inlet at the gas temperature at the inlet. The reactants may be preheated.

### Embodiment 5

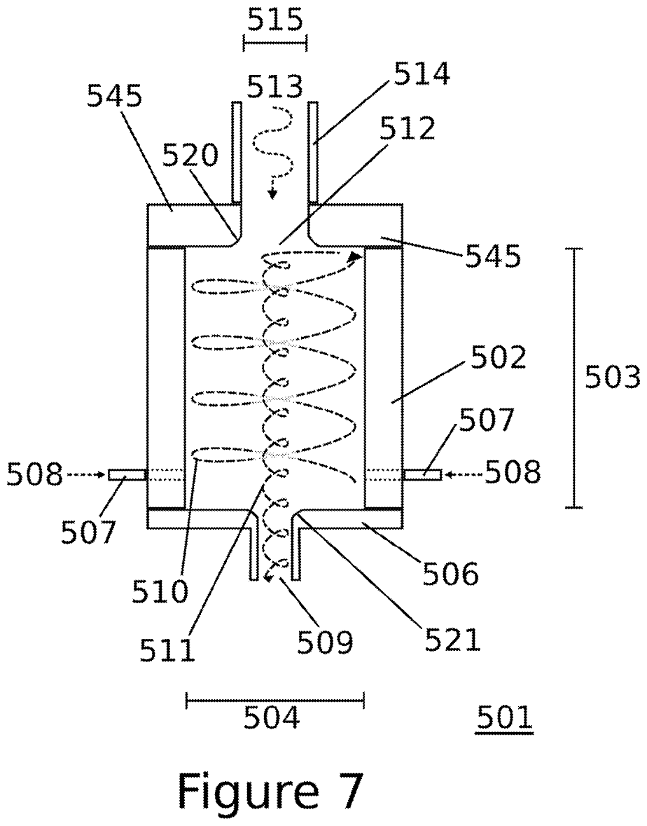

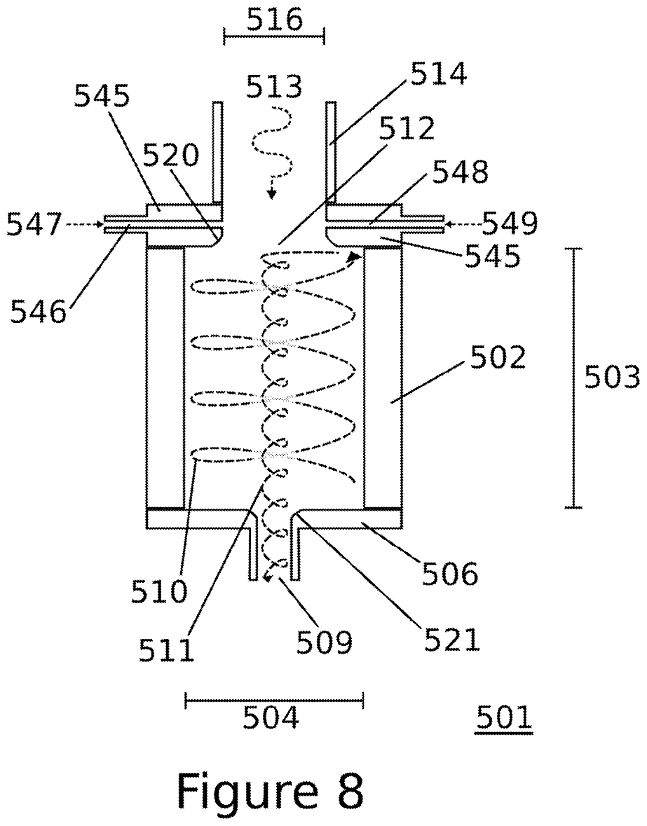

FIG. 7 gives a first cross-sectional diagram through the axial center of an atmospheric microwave plasma reactor according to the fifth embodiment 501. FIG. 8 gives a second cross-sectional diagram through the axial center of an atmospheric microwave plasma reactor according to the fifth embodiment 501. Equivalent elements to previously described embodiments are not repeated, details can be found with the initial description above.

In the fifth embodiment 501 the microwave inlet 512 has been moved to the top of the reactor, by replacing the top flange 105 of the first embodiment 101 with a microwave inlet top flange 545 which is airtight and in electrical contact with the reactor body 502. In this embodiment the microwave inlet 512 does not penetrate the reactor body 502. The waveguide 514 has also been moved to the top of the reactor and matches the microwave inlet 512 dimensions. FIG. 7 is the cross-section through the reactor showing the narrower E-plane dimension 515, while FIG. 8 is the cross-section through the reactor showing the broader H-plane dimension 516. The microwave radiation 513 is preferably in transverse electric one zero (TE10) mode, where the electric field is perpendicular to the direction of propagation.

Moving the microwave inlet 512 the microwave inlet top flange 545 removes the hole for the microwave inlet (see for example the microwave inlet 112 in FIG. 1) with less disturbance to the walls of the reactor body the desired fluid flow pattern through the plasma reactor may be easier to maintain, increasing plasma stability.

The fifth embodiment 501 may additionally include a first microwave top flange gas inlet 546 through which a ninth portion of reactants 547 can be injected, as well as a second microwave top flange gas inlet 548 through which a tenth portion of reactants 549 can be injected. The first microwave top flange gas inlet 546 and second microwave top flange gas inlet 548 and the respective ninth portion of reactants 547 and tenth portion of reactants 549 can be used to encourage the transition from the upward helical flow 510 to the downward helical flow 511 as the gases reach the top of the reactor body 502. Such flows may also help prevent gases and solids in the upward helical flow 510 from entering the microwave inlet 512. Additionally, these flows can be pulsed to push solid deposits out of the microwave inlet 512. Inlets could also be included on the H-plane, though such inlets may have high electric fields which could encourage plasma formation in the microwave inlet 512.

As described with a rectangular waveguide 514 and rectangular microwave inlet 512 the addition of a reactant inlet providing a downward helical swirl would be difficult, though a laminar axial flow inlet could easily be added. However, the rectangular waveguide and microwave inlets could be replaced with a cylindrical waveguide and a cylindrical microwave inlet, in such a system a downward helical swirl could be added.

For the microwave radiation 513 to form a plasma within the reactor body 502 of the plasma reactor according to the fifth embodiment 501 the dimensions of the cylindrical inner surface height 503 and the cylindrical inner surface diameter 504 are dependent on the wavelength of the microwave radiation 513. For a given microwave radiation 513 having a (dominant) free-space wavelength of λ, the cylindrical inner surface height 503 (L1) is preferably 0.6λ≤L1≤0.95λ, more preferably 0.65λ≤L1≤0.8λ. The cylindrical inner surface diameter 504 (d1) is preferably 0.65λ≤d1≤λ, more preferably 0.75λ≤d1≤0.85λ.

The selection of the size of the microwave inlet 512 is also very important to the operation of the plasma reactor according to the fifth embodiment 501. For unloaded waveguides (i.e., without a dielectric), the E-plane dimension 515 (E1) is preferably 0.15λ≤E1≤0.45λ, more preferably 0.3λ≤E1≤0.4λ. The H-plane dimension 516 (H1) is preferably 0.5λ≤H1≤0.9λ, more preferably 0.6λ≤H1≤0.8λ.

Including the waveguide rounded edge 520 and outlet rounded edge 521 will improve performance and extend the life of the plasma reactor. The waveguide rounded edge 520 and outlet rounded edge 521 preferably have a radius of curvature (rc1) where 0.02λ≤r1≤0.2λ, more preferably 0.03λ≤r1≤0.1λ.

While FIG. 7 depicts two swirl reactant inlets 507, a single or more than two swirl reactant inlets 507 could also be used. Further, although FIG. 5 depicts the swirl reactant inlets 507 penetrating the reactor body 502 with a tangential component to the angle, additional or alternatively the swirl reactant inlets 507 could be part of the bottom flange 506 if there is a tangential component to the angle to drive the upward helical flow 510 followed by the downward helical flow 511.

To form a stable plasma within the plasma reactor according to the fifth embodiment 501 the flow rates of the first portion of reactants 508 (r1), ninth portion of reactants 547 (r9), and tenth portion of reactants 549 (r10) must be controlled. Preferably the volume of the sum of reactants flowing (R=r1+r9+r10) into the plasma reactor according to the fifth embodiment 501 is related to the volume of the reactor body 502 V=πL1(d1/2)\hat{ }2 through the residence time tau (volume of the reactor divided by the volume throughput of the reactants): the residence time should be 0.2<tau<1.5 seconds, or preferably 0.5<tau<1 seconds. To maintain the desired fluid dynamics the majority of the reactants flowing through the reactor are injected as the first portion of reactants 508, preferably 0.75≤r1/R≤1, more preferably 0.8≤r1/R≤1. The combined surface area of the single or multiple swirl reactant inlet(s) 507 will determine the velocity the first portion of reactants 508. To maintain the desired fluid dynamics the velocity (v) of the first portion of reactants 508 exiting the swirl reactant inlet 507 are preferably 0.2<v/v_sound<0.9, more preferably 0.5≤v/v_sound≤0.7, where v_sound is the sound speed in the reactants introduced through the inlet at the gas temperature at the inlet. The reactants may be preheated.

### Embodiment 6

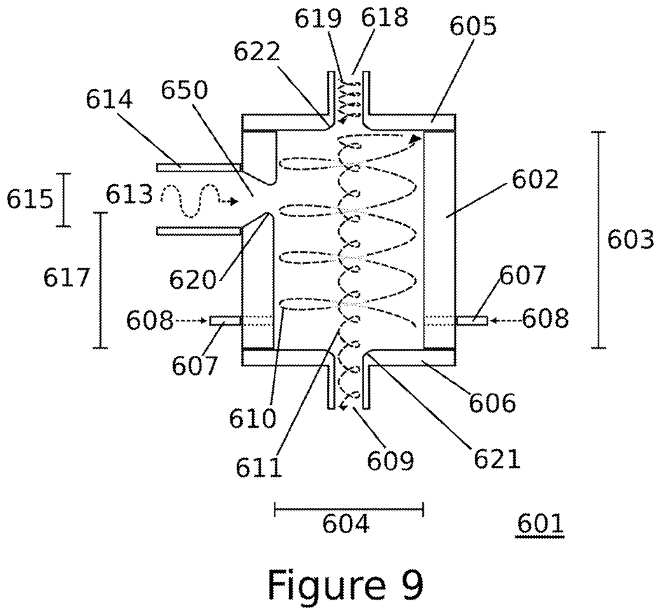

FIG. 9 gives a cross-sectional diagram through the axial center of an atmospheric microwave plasma reactor according to the sixth embodiment 601. Equivalent elements to previously described embodiments are not repeated, details can be found with the initial description above.

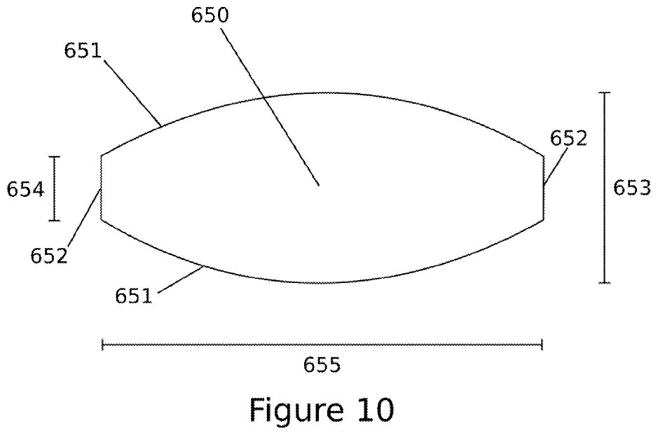

In the sixth embodiment 601 the microwave inlet 112 of the first embodiment 101, is replaced with a tapered microwave inlet 650 through which microwave radiation 613 enters the reactor body 602. Unlike the previous embodiments where the microwave inlets 112/212/312/412/512 had a cuboid shape, the tapered microwave inlet 650 has a trapezoidal pyramid shape. FIG. 10 gives a projection of the shape of the tapered microwave inlet 650 as it enters the reactor body 602. While the shape of the tapered microwave inlet 650 is a trapezoidal pyramid, it penetrates the curved inner surface of the reactor body 602, resulting in curved H-plane surfaces 651 and E-plane walls 652. Due to the curved H-plane surfaces 651 there is a maximum E-plane dimension 653 and a minimum E-plane dimension 654 for the tapered microwave inlet 650. Between the two E-plane walls 652 there is a H-plane dimension 655 for the tapered microwave inlet 650. Reducing the area of the microwave inlet by tapering may help better maintain the desired fluid flow pattern through the plasma reactor, increasing plasma stability. Further, having the maximum E-plane dimension 653 in the middle and the minimum E-plane dimensions 654 on the E-plane walls 652 may help prevent plasma formation within the tapered microwave inlet 650, since the electric field will have the maximum value at the center while the electric field will go to zero at the sides. Thus, this geometry can be used to reduce the size of the microwave inlet as much as possible without causing plasma formation.

Alternatively, the projection of the tapered microwave inlet could be made rectangular by completing the reduction before the tapered microwave inlet 650 fully penetrates the reactor body 602.

While FIG. 9 shows tapering along the height of the E-plane, a similar taper could be made along the H-plane. The amount the H-plane could be tapered is more limited, if tapered too much microware reflection will increase. Finding the balance between increased reflection and improved reactor dynamics due to a smaller tapered microwave inlet 650 is left to one of ordinary skill in the art to determine.

While tapered microwave inlet 650 is shown in FIG. 9 to occur within the reactor body 602, the taper could be done further upstream in the waveguide 614 (by tapering the E-plane dimension 615 and/or the H-plane dimension 616), or partly in the waveguide 614 and partly in the reactor body 602.

For the microwave radiation 613 to form a plasma within the reactor body 602 of the plasma reactor according to the sixth embodiment 601 the dimensions of the cylindrical inner surface height 603, the cylindrical inner surface diameter 604, and the distance 617 between the bottom of the tapered microwave inlet and the bottom of the reactor body are dependent on the wavelength of the microwave radiation 613. For a given microwave radiation 613 having a (dominant) free-space wavelength of λ, the cylindrical inner surface height 603 (L1) is preferably 0.6λ≤L1≤1.6λ, more preferably 0.8λ≤L1≤1.2λ. The cylindrical inner surface diameter 604 (d1) is preferably 0.5λ≤d1≤1.3λ, more preferably 0.6λ≤d1≤0.9λ. The distance 617 between the bottom of the tapered microwave inlet and the bottom of the reactor body (L2) is preferably 0.5λ≤L2≤0.75λ, more preferably 0.55λ≤L2≤0.65λ.

The selection of the size of the tapered microwave inlet 650 is also very important to the operation of the plasma reactor according to the sixth embodiment 601. The minimum E-plane dimension at the tapered microwave inlet 654 (E2) is preferably 0.1λ≤E2≤0.4λ, more preferably 0.15λ≤E2≤0.25λ. The maximum E-plane dimension at the tapered microwave inlet 653 (E3) is preferably 0.15λ≤E3≤0.5λ, more preferably 0.2λ≤E3≤0.3λ. The H-plane dimension at the tapered microwave inlet 655 (H2) is preferably 0.5λ≤H2≤0.9λ, more preferably 0.6λ≤H2≤0.8λ.

Including the waveguide rounded edge 620, top inlet rounded edge 622 (when a top reactant inlet 618 is included), and outlet rounded edge 621 will improve performance and extend the life of the plasma reactor. The waveguide rounded edge 620, top inlet rounded edge 622 and outlet rounded edge 621 preferably have a radius of curvature (rc1) where 0.02λ≤rc1≤0.2λ, more preferably 0.03λ≤rc1≤0.1λ.

While FIG. 9 depicts two swirl reactant inlets 607, a single or more than two swirl reactant inlets 607 could also be used. Further, although FIG. 9 depicts the swirl reactant inlets 607 penetrating the reactor body 602 with a tangential component to the angle, additional or alternatively the swirl reactant inlets 607 could be part of the bottom flange 606 if there is a tangential component to the angle to drive the upward helical flow 610 followed by the downward helical flow 611.

To form a stable plasma within the plasma reactor according to the sixth embodiment 601 the flow rates of the first portion of reactants 608 (r1), second portion of reactants 619 (r2), third portion of reactants 624 (r3) (through the congruent flow sweeper gas inlet 623), and fourth portion of reactants 626 (r4) must be controlled (through the counter flow sweeper gas inlet 625). Preferably the volume of the sum of reactants flowing (R=r1+r2+r3+r4) into the plasma reactor according to the sixth embodiment 601 is related to the volume of the reactor body 602 V=πL1(d1/2)\hat{ }2 through the residence time tau (volume of the reactor divided by the volume throughput of the reactants): the residence time should be 0.2<tau<1.5 seconds, or preferably 0.5<tau<1 seconds. To maintain the desired fluid dynamics the majority of the reactants flowing through the reactor are injected as the first portion of reactants 608, preferably 0.75≤r1/R≤1, more preferably 0.8≤r1/R≤1. The combined surface area of the single or multiple swirl reactant inlet(s) 607 will determine the velocity the first portion of reactants 608. To maintain the desired fluid dynamics the velocity (v) of the first portion of reactants 608 exiting the swirl reactant inlet 607 are preferably 0.2≤v/v_sound≤0.9, more preferably 0.5≤v/v_sound≤0.7, where v_sound is the sound speed in the reactants introduced through the inlet at the gas temperature at the inlet. The reactants may be preheated.

### Embodiment 7

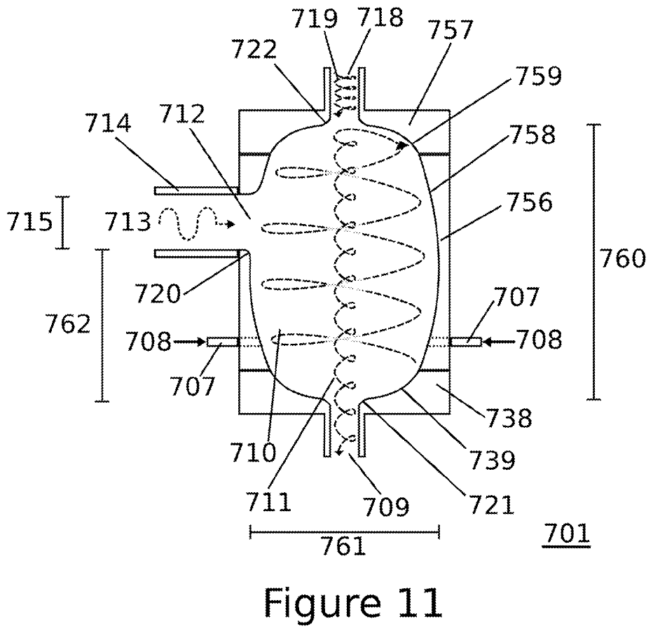

FIG. 11 gives a cross-sectional diagram through the axial center of an atmospheric microwave plasma reactor according to the seventh embodiment 701. Equivalent elements to previously described embodiments are not repeated, details can be found with the initial description above. Further a second cross-sectional diagram through the center of the microwave inlet is not provided as it is equivalent to that of the first embodiment, see FIG. 2.

In the seventh embodiment 701 the reactor body 102, bottom flange 106, and the top flange 105 of the first embodiment 101, are replaced with an ellipsoidal reactor body 756, a bowl bottom flange 738, and a bowl top flange 757, respectively, which are airtight and in electrical contact. The bowl bottom flange 738 has a bowl inner surface 739, the ellipsoidal reactor body 756 has a curved inner surface 758, and the bowl top flange 757 has a bowl inner surface 759. Together the inner surfaces (739, 758, 759) form an ellipsoidal inner plasma reactor surface having an ellipsoid height 760 and an ellipsoid diameter 761. There is a distance 762 between the bottom of the ellipsoidal inner surface of the bowl bottom flange and the bottom of the microwave inlet 712. The ellipsoidal inner reactor surface has no sharp transitions which may improve plasma stability.

For the microwave radiation 713 to form a plasma within the ellipsoidal reactor body 756 of the plasma reactor according to the seventh embodiment 701 the dimensions of the ellipsoid height 760, the cylindrical inner surface diameter 304, and distance 762 between the bottom of the ellipsoidal inner surface of the bowl bottom flange and the bottom of the microwave inlet are dependent on the wavelength of the microwave radiation 713. For a given microwave radiation 713 having a (dominant) free-space wavelength of A, the ellipsoid height 760 (L4) is preferably 1.1λ≤L4≤1.9λ, more preferably 1.4λ≤L4≤1.65λ. The ellipsoid cylindrical inner surface diameter 761 (d2) is preferably 0.6λ≤d2≤1.1λ, more preferably 0.75λ≤d2≤0.95λ. The distance 762 between the bottom of the ellipsoidal inner surface of the bowl bottom flange and the bottom of the microwave inlet (L5) is preferably 0.65λ≤L5≤1.2λ, more preferably 0.75λ≤L5≤0.95λ.

The selection of the size of the microwave inlet 712 is also very important to the operation of the plasma reactor according to the seventh embodiment 701. For unloaded waveguides (i.e., without a dielectric), the E-plane dimension 715 (E1) is preferably 0.15λ≤E1≤0.45λ, more preferably 0.3λ≤E1≤0.4λ. The H-plane dimension 716 (H1) is preferably 0.5λ≤H1≤0.9λ, more preferably 0.6λ≤H1≤0.8λ.

Including the waveguide rounded edge 720, top inlet rounded edge 722 (when a top reactant inlet 718 is included), and outlet rounded edge 721 will improve performance and extend the life of the plasma reactor. The waveguide rounded edge 720, top inlet rounded edge 722, and outlet rounded edge 721 preferably have a radius of curvature (r1) where 0.02λ≤rc1≤0.2λ, more preferably 0.03λ≤rc1≤0.1λ.

While FIG. 11 depicts two swirl reactant inlets 707, a single or more than two swirl reactant inlets 707 could also be used. Further, although FIG. 11 depicts the swirl reactant inlets 707 penetrating the ellipsoidal reactor body 756 with a tangential component to the angle, additional or alternatively the swirl reactant inlets 707 could be part of the bowl bottom flange 738 if there is a tangential component to the angle to drive the upward helical flow 710 followed by the downward helical flow 711.

To form a stable plasma within the plasma reactor according to the seventh embodiment 701 the flow rates of the first portion of reactants 708 (r1), second portion of reactants 719 (r2), third portion of reactants 724 (r3) (through the congruent flow sweeper gas inlet 723), and fourth portion of reactants 726 (r4) (through the counter flow sweeper gas inlet 725) must be controlled. Preferably the volume of the sum of reactants flowing (R=r1+r2+r3+r4) into the plasma reactor according to the seventh embodiment 701 is related to the ellipsoidal volume of the space enclosed by the bowl top flange 757, the ellipsoidal reactor body 756, and the bowl bottom flange 737 V=(π/6)L4(d2)\hat{ }2 (assuming spheroidal dimensions) through the residence time tau (volume of the reactor divided by the volume throughput of the reactants): the residence time should be 0.2<tau<1.5 seconds, or preferably 0.5<tau<1 seconds. To maintain the desired fluid dynamics the majority of the reactants flowing through the reactor are injected as the first portion of reactants 708, preferably 0.75≤r1/R≤1, more preferably 0.8≤r1/R≤1. The combined surface area of the single or multiple swirl reactant inlet(s) 707 will determine the velocity the first portion of reactants 708. To maintain the desired fluid dynamics the velocity (v) of the first portion of reactants 708 exiting the swirl reactant inlet 707 are preferably 0.2≤v/v_sound≤0.9, more preferably 0.5≤ v/v_sound≤0.7, where v_sound is the sound speed in the reactants introduced through the inlet at the gas temperature at the inlet. The reactants may be preheated.

For all embodiments the first portion of reactants 108/208/308/408/508/608/708, second portion of reactants 119/219/319/419/619/719, third portion of reactants 124/224/324/624/724, fourth portion of reactants 126/226/326/626/726, fifth portion of reactants 233, sixth portion of reactants 236, seventh portion of reactants 442, eighth portion of reactants 444, ninth portion of reactants 547, and tenth portion of reactants 549 may include nitrogen, oxygen, argon, helium, neon, hydrogen, chlorine, fluorine, ammonia, carbon dioxide, carbon monoxide, hydrogen chloride, nitrous oxide, nitrogen trifluoride, sulfur dioxide, sulfur hexafluoride, methane, acetylene, ethane, ethene, propane, propene, butane, butene, gasoline, diesel, kerosene, natural gas, biogas, other hydrocarbons, chlorofluorocarbons, methanol, ethanol, propanol, butanol, other alcohols, air, water, or combinations thereof. Preferably the first portion of reactants 108/208/308/408/508/608/708 includes at least (1) methane, (2) carbon dioxide, (3) carbon dioxide and methane, (4) water and methane, (5) carbon dioxide and water, or (6) hydrogen.

For many applications molecular reforming chemistry can be driven by the plasma, thus the composition and molar flow rate of the reactants through the sum of all inlets may differ from the composition and molar flow rate at the outlet 109/209/309/409/509/609/709. Some reactions can result in the formation of solids, in these cases the flows through the outlet 109/209/309/409/509/609/709 have two phases (gas and solid). For example, the pyrolysis of hydrocarbons (methane, acetylene, ethane, ethene, propane, propene, butane, butene, natural gas, biogas) will result in the formation of hydrogen-rich gas and solid carbon.

Preferably the reactor body 102/202/302/402/502/602, ellipsoidal reactor body 756, top flange 105/205/305/405/605, microwave inlet top flange 545, bowl top flange 757, bottom flange 106/406/506/606, conical bottom flange 227, bowl bottom flange 338/738, and waveguide 114/214/314/414/514/614/714 are made of aluminum, steel, nickel, or brass.

It should be noted the various combinations of the seven embodiments presented could also be made from this disclosure. For example, an ellipsoidal reactor could be made that has microwaves entering from the top flange, or a cylindrical body with a bowl top flange and a cone bottom flange with microwaves entering a 90 degree rotation. It is left to one of ordinary skill in the art to pick the particular parts of each of these embodiments for a particular reforming or pyrolyzing application.

We claim:

1. A microwave-based plasma reactor, comprising:
a reactor body having a cylindrical inner surface with a cylindrical inner surface height and a cylindrical inner surface diameter;
a top flange in electrical contact with the reactor body;
a bottom flange in electrical contact with the reactor body;
a microwave inlet through which microwaves having a microwave wavelength, an E-plane dimension, and an H-plane dimension enter the microwave-based plasma reactor;
a swirl reactant inlet through which a first portion of reactants are injected;
and an outlet through which an outlet product flows.

2. The microwave-based plasma reactor of claim 1, wherein the microwave inlet penetrates the reactor body with the E-plane dimension being parallel and the H-plane dimension being perpendicular to a height dimension of the reactor;
and wherein there is a distance between the bottom of the microwave inlet and the bottom of the reactor body.

3. The microwave-based plasma reactor of claim 2, wherein the cylindrical inner surface height is 0.6 to 1.6 times the microwave wavelength;
wherein the cylindrical inner surface diameter is 0.5 to 1.3 times the microwave wavelength;
and wherein the distance between the bottom of the microwave inlet and the bottom of the reactor body is 0.5 to 0.75 time the microwave wavelength.

4. The microwave-based plasma reactor of claim 3, wherein the E-plane dimension is 0.15 to 0.45 times the microwave wavelength;
and wherein the H-plane dimension is 0.5 to 0.9 times the microwave wavelength.

5. The microwave-based plasma reactor of claim 4, further comprising a waveguide rounded edge and an outlet rounded edge;
wherein a radius of curvature of the waveguide rounded edge and the outlet rounded edge is 0.02 to 0.2 times the microwave wavelength.

6. The microwave-based plasma reactor of claim 3, wherein the microwave inlet tapers to a smaller size as it penetrates the reactor body, having a minimum E-plane dimension, a maximum E-plane dimension, and the H-plane dimension;
wherein the minimum E-plane dimension is 0.1 to 0.4 times the microwave wavelength;
wherein the maximum E-plane dimension is 0.15 to 0.5 times the microwave wavelength;
and wherein the H-plane dimension is 0.5 to 0.9 times the microwave wavelength.

7. The microwave-based plasma reactor of claim 2, wherein the bottom flange has a conical surface having a conical height and a conical angle.

8. The microwave-based plasma reactor of claim 7, wherein the cylindrical inner surface height is 0.5 to 0.9 times the microwave wavelength;
wherein the cylindrical inner surface diameter is 0.7 to 1.1 times the microwave wavelength;
wherein the distance between the bottom of the microwave inlet and the bottom of the reactor body is 0.1 to 0.3 times the microwave wavelength;
wherein the conical height of the bottom flange is 0.15 to 0.6 times the microwave wavelength;
and wherein the conical angle of the bottom flange is 15 to 50 degrees.

9. The microwave-based plasma reactor of claim 8, wherein the E-plane dimension is 0.15 to 0.45 times the microwave wavelength;
and wherein the H-plane dimension is 0.5 to 0.9 times the microwave wavelength.

10. The microwave-based plasma reactor of claim 9, further comprising a waveguide rounded edge and an outlet rounded edge;
wherein a radius of curvature of the waveguide rounded edge and the outlet rounded edge is 0.02 to 0.2 times the microwave wavelength.

11. The microwave-based plasma reactor of claim 2, wherein the bottom flange is a bowl bottom flange having a bowl surface having a bowl height and a bowl radius of curvature.

12. The microwave-based plasma reactor of claim 11, wherein the cylindrical inner surface height is 0.5 to 0.9 times the microwave wavelength;
wherein the cylindrical inner surface diameter is 0.7 to 1.1 times the microwave wavelength;
wherein the distance between the bottom of the microwave inlet and the bottom of the reactor body is 0.1 to 0.3 times the microwave wavelength;
and wherein a radius of curvature of the bowl bottom flange is 1.5 to 3.5 times the microwave wavelength.

13. The microwave-based plasma reactor of claim 12, wherein the E-plane dimension is 0.15 to 0.45 times the microwave wavelength;
and wherein the H-plane dimension is 0.5 to 0.9 times the microwave wavelength.

14. The microwave-based plasma reactor of claim 13, further comprising a waveguide rounded edge and an outlet rounded edge;
wherein the radius of curvature of the waveguide rounded edge and the outlet rounded edge is 0.02 to 0.2 times the microwave wavelength.

15. The microwave-based plasma reactor of claim 1, wherein the microwave inlet penetrates the reactor body with the H-plane dimension being parallel and the E-plane dimension being perpendicular to the height dimension of the reactor;
and wherein there is a distance between the bottom of the microwave inlet and the bottom of the reactor body.

16. The microwave-based plasma reactor of claim 15, wherein the cylindrical inner surface height is 0.6 to 1.3 times the microwave wavelength;
wherein the cylindrical inner surface diameter is 0.45 to 0.95 times the microwave wavelength;
and wherein the distance between the bottom of the microwave inlet and the bottom of the reactor body is 0.1 to 0.3 time the microwave wavelength.

17. The microwave-based plasma reactor of claim 16, wherein the E-plane dimension is 0.15 to 0.45 times the microwave wavelength;
and wherein the H-plane dimension is 0.5 to 0.9 times the microwave wavelength.

18. The microwave-based plasma reactor of claim 17, further comprising a waveguide rounded edge and an outlet rounded edge;
wherein a radius of curvature of the waveguide rounded edge and the outlet rounded edge is 0.02 to 0.2 times the microwave wavelength.

19. The microwave-based plasma reactor of claim 1, wherein the microwave inlet penetrates the top flange.

20. The microwave-based plasma reactor of claim 19, wherein the cylindrical inner surface height is 0.6 to 0.95 times the microwave wavelength;
and wherein the cylindrical inner surface diameter is 0.65 to 1 times the microwave wavelength.

21. The microwave-based plasma reactor of claim 20, wherein the E-plane dimension is 0.15 to 0.45 times the microwave wavelength;
and wherein the H-plane dimension is 0.5 to 0.9 times the microwave wavelength.

22. The microwave-based plasma reactor of claim 21, further comprising a waveguide rounded edge and an outlet rounded edge;
wherein a radius of curvature of the waveguide rounded edge and the outlet rounded edge is 0.02 to 0.2 times the microwave wavelength.

23. The microwave-based plasma reactor of claim 1, wherein the swirl reactant inlet is provided in plurality and the swirl reactant inlet penetrates the reactor body tangential to the cylindrical inner surface.

24. The microwave-based plasma reactor of claim 23, wherein a velocity of the first portion of reactants is 0.2 to 0.9 times a speed of sound within the first portion of reactants.

25. The microwave-based plasma reactor of claim 1, wherein the swirl reactant inlet is provided in plurality and the swirl reactant inlet penetrates the bottom flange.

26. The microwave-based plasma reactor of claim 1, wherein a residence time of the first portion of reactants in the microwave-based plasma reactor is 0.2 to 1.5 seconds.

27. The microwave-based plasma reactor of claim 1, wherein the top flange further comprises a swirl inlet, through which a second portion of reactants flow.

28. The microwave-based plasma reactor of claim 27, further comprising a congruent flow sweeper gas inlet through which a third portion of reactants flow.

29. The microwave-based plasma reactor of claim 27, further comprising a counter flow sweeper gas inlet through which a fourth portion of reactants flow.

30. The microwave-based plasma reactor of claim 1, wherein first portion of reactants contain at least (1) methane, (2) carbon dioxide, (3) carbon dioxide and methane, (4) water and methane, (5) carbon dioxide and water, or (6) hydrogen.
